(19) United States
(12) Patent Application Publication
(10) Pub. No.: US 2026/0351529 A1
(43) Pub. Date: Nov. 5, 2026

(54) SUBSTRATE PROCESSING SYSTEM AND SUBSTRATE PROCESSING METHOD

(71) Applicant: Tokyo Electron Limited, Tokyo (JP)

(72) Inventors: Genki OSADA, Miyagi (JP); Masatomo KITA, Miyagi (JP); Tatsuru OKAMURA, Miyagi (JP); Toshiyuki MAKABE, Miyagi (JP)

(73) Assignee: Tokyo Electron Limited, Tokyo (JP)

(21) Appl. No.: 19/726,306

(22) Filed: Jun. 30, 2026

Related U.S. Application Data
(63) Continuation of application No. PCT/JP2024/045947, filed on Dec. 25, 2024.

(30) Foreign Application Priority Data
Jan. 11, 2024 (JP) 2024-002473

(51) Int. Cl. H01J 37/32

(52) U.S. Cl. CPC H01J 37/32642; H01J 37/32715; H01J 37/32743; H01J 37/32816; H01J 37/32889; H01J 2237/332; H01J 2237/334

(57) ABSTRACT

A disclosed substrate processing system includes a vacuum transfer module, a controller, a plurality of process modules, an aligner, a memory, and an identification processor. The aligner has a stage configured to support a ring member, and an optical sensor configured to detect a shape of the ring member placed on the stage. The memory stores a table including feature information indicating a feature of each of a plurality of ring members, the feature information being associated with an identifier of each of the process modules. The identification processor extracts the feature information of the ring member from the shape detected by the optical sensor, and refers to the table to identify one of the process modules to which the ring member is to be transferred, from the identifier associated with the feature information.

### CROSS-REFERENCE TO RELATED APPLICATIONS

This application is a continuation application of PCT Application No. PCT/JP2024/045947, filed on Dec. 25, 2024, which claims the benefit of priority from Japanese Patent Application No. 2024-002473, filed on Jan. 11, 2024. The entire contents of the above listed PCT and priority applications are incorporated herein by reference.

### BACKGROUND

### Field

The present disclosure relates to a substrate processing system and a substrate processing method.

### Description of the Related Art

Substrate processing systems capable of performing various processes such as plasma processing on a substrate are known. A substrate processing system includes a process module having a processing chamber and a substrate support. The substrate support is provided in the processing chamber and supports a ring member disposed thereon. Japanese Unexamined Patent Application Publication No. 2022-02255 below discloses a technique for replacing a ring member disposed on a substrate support.

### SUMMARY

In one exemplary embodiment, a substrate processing system is provided. The substrate processing system includes a vacuum transfer module, a controller, a plurality of process modules, an aligner, a memory, and an identification processor. The vacuum transfer module has a transfer chamber and a transfer robot. The transfer chamber is configured to be depressurized. The transfer robot is configured to transfer a substrate through the transfer chamber. The controller is configured to control the transfer robot. Each of the plurality of process modules has a processing chamber and a substrate support. The processing chamber is connected to the transfer chamber. The substrate support is disposed in the processing chamber. Each of the plurality of process modules is configured to perform substrate processing on a substrate on the substrate support. The aligner has a stage and an optical sensor. The stage is configured to support a ring member placed thereon. The optical sensor is configured to detect a shape of the ring member placed on the stage. The memory is configured to store a table including feature information indicating a feature of each of a plurality of ring members. The feature information is associated with an identifier of each of the plurality of process modules. The identification processor extracts the feature information of the ring member from the shape of the ring member detected by the optical sensor, and refers to the table stored in the memory to identify one of the plurality of process modules to which the ring member is to be transferred, from the identifier associated with the feature information.

### BRIEF DESCRIPTION OF THE DRAWINGS

FIG. 1 is a diagram showing a substrate processing system according to one exemplary embodiment.

FIG. 2 is a diagram schematically showing a plasma processing apparatus according to one exemplary embodiment.

FIG. 3 is a partially enlarged cross-sectional view of a substrate support of a plasma processing apparatus according to one exemplary embodiment.

FIG. 4 is a perspective view showing a stocker module according to one embodiment.

FIG. 5 is an end view of a stocker module according to one embodiment.

FIG. 6 is a plan view of an edge ring and an aligner according to one embodiment.

FIG. 7 is a plan view of a cover ring and an aligner according to one embodiment.

FIG. 8 is a flowchart showing a substrate processing method according to one exemplary embodiment.

### DETAILED DESCRIPTION

In the following description, with reference to the drawings, the same reference numbers are assigned to the same components or to similar components having the same function, and overlapping description is omitted.

Hereinafter, various exemplary embodiments will be described in detail with reference to the drawings. In each drawing, the same or equivalent portions are denoted by the same reference symbols.

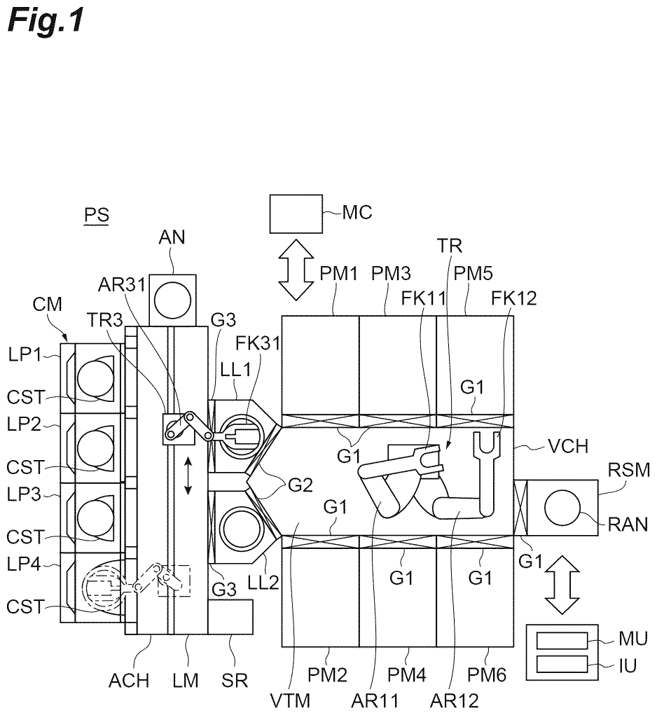

FIG. 1 is a diagram showing a substrate processing system according to one exemplary embodiment. As shown in FIG. 1, a substrate processing system PS includes a vacuum transfer module VTM, a controller MC, a plurality of process modules PM1 to PM6, an aligner RAN, a memory MU, and an identification processor IU. In one embodiment, the substrate processing system PS may further include a stocker module RSM, a loader module LM, and at least one load lock module. The substrate processing system PS includes two load lock modules LL1 and LL2 as the at least one load lock module. The substrate processing system PS may further include at least one load port, a substrate inspection module CM, an aligner AN, and a storage SR. The substrate processing system PS includes four load ports LP1 to LP4 as the at least one load port.

The loader module LM is an example of an atmospheric transfer module. In one embodiment, the loader module LM includes a transfer chamber ACH. The transfer chamber ACH is an example of another transfer chamber. The pressure in the transfer chamber ACH of the loader module LM can be set to atmospheric pressure. The loader module LM may have an FFU (Fan Filter Unit). The loader module LM is, for example, an EFEM (Equipment Front End Module). The loader module LM is disposed between each of the load ports LP1 to LP4 and each of the load lock modules LL1 and LL2. The load ports LP1 to LP4 are arranged along one of a pair of edges along the longitudinal direction of the loader module LM. The load lock modules LL1 and LL2 are arranged along the other of the pair of edges along the longitudinal direction of the loader module LM. Each of the load ports LP1 to LP4 is configured to support a cassette CST placed thereon. The cassette CST is a container that accommodates a plurality of substrates W therein. The cassette CST is, for example, a FOUP (Front-Opening Unified Pod).

In one embodiment, the loader module LM includes a transfer robot TR3. The transfer robot TR3 is an example of another transfer robot. The transfer robot TR3 is provided in the transfer chamber ACH of the loader module LM. The transfer robot TR3 may include an articulated arm AR31 and an end effector FK31. The end effector FK31 is attached to a tip of the articulated arm AR31 and is configured to support a substrate W placed thereon. The transfer robot TR3 is configured to transfer the substrate W through the transfer chamber ACH. For example, the transfer robot TR3 transfers the substrate W based on an operation instruction output by the controller MC described later. The transfer robot TR3 transfers the substrate W between any two of the cassette CST placed on at least one of the load ports LP1 to LP4, the load lock modules LL1 and LL2, the aligner AN, and the storage SR.

The aligner AN is disposed along one of a pair of edges along the short-side direction of the loader module LM. The aligner AN may be disposed along an edge along the longitudinal direction of the loader module LM. Further, the aligner AN may be disposed in the transfer chamber ACH of the loader module LM. The aligner AN has a stage, an optical sensor, and the like. The stage of the aligner AN is rotatable and supports the substrate W placed thereon. The aligner AN detects an angular position of a marker (for example, a notch) of the substrate W on the stage and a center position of the substrate W on the stage using the optical sensor. The controller MC controls rotation of the stage of the aligner AN to correct the angular position of the marker (for example, a notch) of the substrate W on the stage to a reference angular position, thereby correcting a deviation amount of the angular position of the substrate W. Further, the controller MC controls a position of the end effector FK31 when receiving the substrate W from the aligner AN onto the end effector FK31, in order to position the center of the substrate W at a predetermined position on the end effector FK31.

The storage SR is disposed along an edge along the longitudinal direction of the loader module LM. The storage SR may be disposed along an edge along the short-side direction of the loader module LM. Further, the storage SR may be provided inside the loader module LM. The storage SR is configured to accommodate the substrate W therein.

The substrate inspection module CM may be provided inside the loader module LM or the vacuum transfer module VTM. The substrate inspection module CM may be connected to the loader module LM below the load ports LP1 to LP4. The substrate inspection module CM is not limited to the above-mentioned locations and can be installed at any location. The substrate inspection module CM is configured to acquire an image of the substrate W.

In one embodiment, the load lock modules LL1 and LL2 are connected to the loader module LM. Each of the load lock modules LL1 and LL2 may be connected to the loader module LM through a gate valve G3. In the example shown in FIG. 1, each of the load lock modules LL1 and LL2 is connected to the vacuum transfer module VTM through a gate valve G2. Each of the load lock modules LL1 and LL2 may be disposed between the vacuum transfer module VTM and the loader module LM. Each of the load lock modules LL1 and LL2 provides a preliminary depressurization chamber.

The vacuum transfer module VTM has at least one transfer chamber and at least one transfer robot. In the example shown in FIG. 1, the vacuum transfer module VTM has a transfer chamber VCH and a transfer robot TR as the at least one transfer chamber and the at least one transfer robot. The transfer chamber VCH is configured to be depressurized. The transfer robot TR is configured to transfer the substrate W through the transfer chamber VCH. In one embodiment, the aligner RAN is connected to the transfer chamber VCH of the vacuum transfer module VTM.

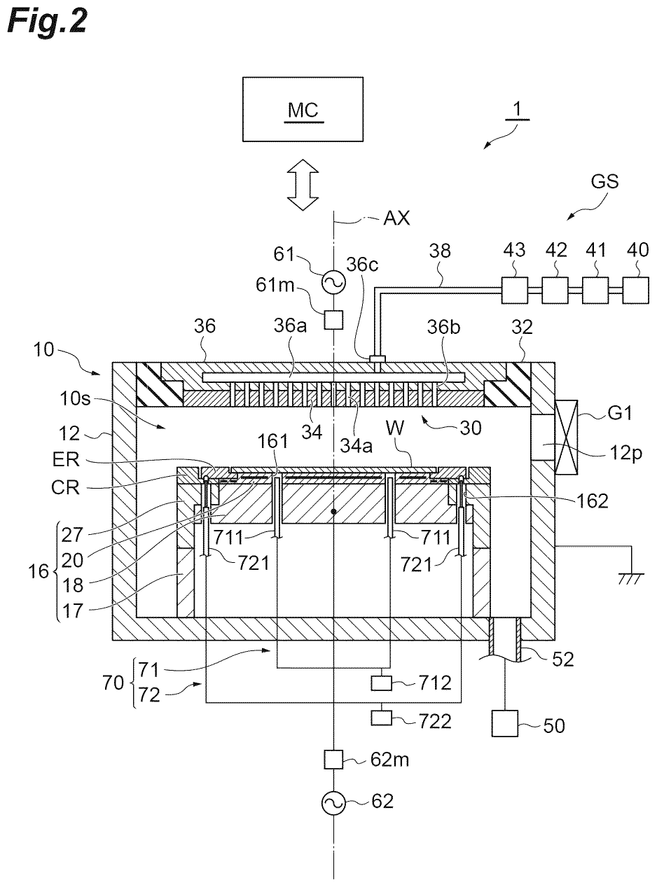

Each of the plurality of process modules PM1 to PM6 has a processing chamber 10 and a substrate support 16 (see FIG. 2). The processing chamber 10 is connected to the vacuum transfer module VTM. In the example shown in FIG. 1, the process modules PM1 to PM6 are connected to the vacuum transfer module VTM through gate valves G1.

The transfer robot TR may include articulated arms AR11 and AR12 and end effectors FK11 and FK12. The end effector FK11 is attached to a tip of the articulated arm AR11 and is configured to support the substrate W placed thereon. The end effector FK12 is attached to a tip of the articulated arm AR12 and is configured to support the substrate W placed thereon. For example, the transfer robot TR transfers the substrate W based on an operation instruction output by the controller MC described later. The transfer robot TR holds the substrate W by the end effectors FK11 and FK12. The transfer robot TR is configured to transfer the substrate W or a ring member R on the paths between the load lock modules LL1 and LL2, the process modules PM1 to PM6, and the stocker module RSM. In one embodiment, the ring member R is an edge ring ER (focus ring) or a cover ring CR. The edge ring ER is configured to surround the substrate W on the substrate support 16. The cover ring CR is configured to surround the edge ring ER. Details of the edge ring ER and the cover ring CR will be described later.

In one embodiment, the stocker module RSM is connected to the transfer chamber VCH of the vacuum transfer module VTM. In one example, the stocker module RSM is connected to the transfer chamber VCH through a gate valve G1. The stocker module RSM is configured to accommodate the ring member R therein. The stocker module RSM is also referred to as a ring stocker. In the example shown in FIG. 1, the aligner RAN is disposed in the stocker module RSM. Details of the stocker module RSM and the aligner RAN will be described later.

In one embodiment, each of the process modules PM1 to PM6 is configured to perform dedicated processing on the substrate W. At least one of the process modules PM1 to PM6 is a substrate processing apparatus such as a plasma processing apparatus 1 described later.

The controller MC is configured to control each part of the substrate processing system PS. The controller MC may be a computer including a processor, a memory, an input device, a display device, and the like. The controller MC executes a control program stored in the memory and controls each part of the substrate processing system PS based on recipe data stored in the memory. Transfer methods according to various exemplary embodiments described later are performed in the substrate processing system PS by control of each part of the substrate processing system PS by the controller MC. The controller MC is configured to control the transfer robots TR and TR3. The controller MC may also serve as the memory MU and the identification processor IU. Details of the memory MU and the identification processor IU will be described later.

Hereinafter, reference is made to FIG. 2. FIG. 2 is a diagram schematically showing a plasma processing apparatus according to one exemplary embodiment. The plasma processing apparatus 1 shown in FIG. 2 is adopted as at least one process module among the process modules PM1 to PM6. The plasma processing apparatus 1 is an example of a substrate processing apparatus.

The plasma processing apparatus 1 is a capacitively coupled plasma processing apparatus. The plasma processing apparatus 1 includes a processing chamber 10. The processing chamber 10 provides an interior space 10s therein. The central axis of the interior space 10s is an axis AX extending in the vertical direction.

In one embodiment, the processing chamber 10 includes a chamber body 12. The chamber body 12 has a substantially cylindrical shape. The interior space 10s is provided in the chamber body 12. The chamber body 12 is formed of, for example, aluminum. The chamber body 12 is electrically grounded. A film having plasma resistance is formed on the inner wall surface of the chamber body 12, that is, the wall surface defining the interior space 10s. This film may be a ceramic film such as a film formed by anodizing treatment or a film formed from yttrium oxide.

A passage 12p is formed in a side wall of the chamber body 12. The substrate W or the ring member R passes through the passage 12p when being transferred between the processing chamber 10 and the transfer chamber VCH. A gate valve G1 is provided along the side wall of the chamber body 12 for opening and closing the passage 12p.

The plasma processing apparatus 1 further includes a substrate support 16. The substrate support 16 is provided in the processing chamber 10. The substrate support 16 is configured to support the substrate W placed thereon. The substrate W has a substantially disk shape. Details of the substrate support 16 will be described later.

The plasma processing apparatus 1 may further include an upper electrode 30. The upper electrode 30 is provided above the substrate support 16. The upper electrode 30 closes an upper opening of the chamber body 12 together with a member 32. The member 32 has insulating properties. The upper electrode 30 is supported on an upper portion of the chamber body 12 through the member 32.

The upper electrode 30 includes a ceiling plate 34 and a support 36. A lower surface of the ceiling plate 34 defines the interior space 10s. The ceiling plate 34 provides a plurality of gas holes 34a. Each of the plurality of gas holes 34a penetrates the ceiling plate 34 in the plate thickness direction (vertical direction) and opens toward the interior space 10s. The ceiling plate 34 is formed of, for example, silicon. Alternatively, the ceiling plate 34 may have a structure in which a plasma-resistant film is provided on a surface of an aluminum member. This film may be a ceramic film such as a film formed by anodizing treatment or a film formed from yttrium oxide.

The support 36 detachably supports the ceiling plate 34. The support 36 is formed of a conductive material such as aluminum. The support 36 provides a gas diffusion chamber 36a and a plurality of gas holes 36b therein. The plurality of gas holes 36b extend downward from the gas diffusion chamber 36a and communicate with the plurality of gas holes 34a, respectively. The support 36 has a gas introduction port 36c. The gas introduction port 36c is connected to the gas diffusion chamber 36a. A gas supply pipe 38 is connected to the gas introduction port 36c.

A gas source group 40 is connected to the gas supply pipe 38 through a valve group 41, a flow rate controller group 42, and a valve group 43. The gas source group 40, the valve group 41, the flow rate controller group 42, and the valve group 43 constitute a gas supply GS. The gas source group 40 includes a plurality of gas sources. Each of the valve group 41 and the valve group 43 includes a plurality of valves (for example, on-off valves). The flow rate controller group 42 includes a plurality of flow rate controllers. Each of the plurality of flow rate controllers of the flow rate controller group 42 is a mass flow controller or a pressure-controlled flow rate controller. Each of the plurality of gas sources of the gas source group 40 is connected to the gas supply pipe 38 through a corresponding valve of the valve group 41, a corresponding flow rate controller of the flow rate controller group 42, and a corresponding valve of the valve group 43. The plasma processing apparatus 1 can supply gas from one or more gas sources selected from among the plurality of gas sources of the gas source group 40 to the interior space 10s at individually adjusted flow rates.

The processing chamber 10 provides an exhaust path around the substrate support 16. An exhaust pipe 52 is connected to a bottom portion of the processing chamber 10 below the exhaust path. An exhaust device 50 is connected to the exhaust pipe 52. The exhaust device 50 has a pressure controller such as an automatic pressure control valve and a vacuum pump such as a turbomolecular pump, and can reduce the pressure of the interior space 10s.

The plasma processing apparatus 1 further includes a radio frequency power supply 61. The radio frequency power supply 61 is a power supply that generates source radio frequency power. The source radio frequency power is used to generate plasma from a gas in the processing chamber 10. The frequency of the source radio frequency power (source frequency) is a frequency in the range of 27 to 100 MHz. The radio frequency power supply 61 is connected to the upper electrode 30 through a matching circuit 61m. The matching circuit 61m is configured to match an impedance on a load side (upper electrode 30 side) of the radio frequency power supply 61 to an output impedance of the radio frequency power supply 61. Note that the radio frequency power supply 61 may be connected to the substrate support 16 (for example, a lower electrode such as the base plate 18) through the matching circuit 61m instead of the upper electrode 30.

The plasma processing apparatus 1 further includes a bias power supply 62. The bias power supply 62 is electrically coupled to the substrate support 16 (for example, a lower electrode such as the base plate 18) and supplies an electrical bias to the substrate support 16 for attracting ions from the plasma to the substrate W. The electrical bias has a bias frequency. The bias frequency may be lower than the source frequency. The bias frequency is, for example, a frequency in the range of 100 kHz to 13.56 MHz.

The electrical bias may be bias radio frequency power having a bias frequency. In this case, the bias power supply 62 is connected to the substrate support 16 (for example, a lower electrode such as the base plate 18 or another electrode of the substrate support 16) through a matching circuit 62m. The matching circuit 62m is configured to match an impedance on a load side of the bias power supply 62 to an output impedance of the bias power supply 62. Alternatively, the electrical bias may be a sequence of voltage pulses. The voltage pulses may be pulses of a DC voltage. In this case, the plasma processing apparatus 1 does not include the matching circuit 62m.

The substrate support 16 includes the base plate 18 and an electrostatic chuck 20. The base plate 18 has a substantially disk shape. The substrate support 16 may further include a base 17 and an insulator 27. The base plate 18 may be formed of a metal such as aluminum and may constitute a lower electrode. The base 17 is provided on a bottom portion of the processing chamber 10. The insulator 27 is provided on the base 17. The insulator 27 is formed of an insulating material such as quartz and extends to surround an outer periphery of the base plate 18. The electrostatic chuck 20 is provided on the base plate 18.

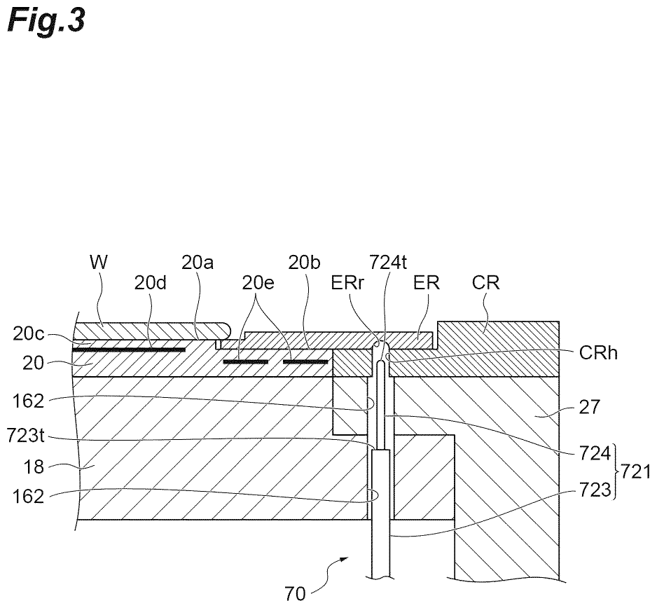

Hereinafter, reference is made to FIG. 3 together with FIG. 2. FIG. 3 is a partially enlarged cross-sectional view of the substrate support of the plasma processing apparatus according to one exemplary embodiment. An upper surface of the electrostatic chuck 20 includes a substrate support surface 20a and a ring support surface 20b. The substrate support surface 20a is a substantially circular surface, and its central axis is the axis AX. The electrostatic chuck 20 supports the substrate W placed on the substrate support surface 20a.

The ring support surface 20b is an annular surface extending around the axis AX on the outside of the substrate support surface 20a. The electrostatic chuck 20 supports the edge ring ER placed on the ring support surface 20b. The edge ring ER has an annular shape. The substrate W is disposed in a region surrounded by the edge ring ER. The edge ring ER is formed of, for example, a conductive material such as silicon or silicon carbide. The edge ring ER may be formed of an insulating material such as quartz.

The electrostatic chuck 20 has a dielectric portion 20c, a first chuck electrode 20d, and a second chuck electrode 20e. The dielectric portion 20c is formed of a ceramic such as aluminum oxide. The dielectric portion 20c has a substantially disk shape and provides the substrate support surface 20a and the ring support surface 20b.

The first chuck electrode 20d and the second chuck electrode 20e are disposed in the dielectric portion 20c and below the substrate support surface 20a. When a voltage is applied to the first chuck electrode 20d, the electrostatic chuck 20 generates an electrostatic attraction force to attract and hold the substrate W on the substrate support surface 20a. The second chuck electrode 20e is disposed in the dielectric portion 20c and below the ring support surface 20b. When a voltage is applied to the second chuck electrode 20e, the electrostatic chuck 20 generates an electrostatic attraction force to attract and hold the edge ring ER on the ring support surface 20b. Note that in the illustrated example, the electrostatic chuck 20 includes a monopolar electrostatic chuck that holds the substrate W and a bipolar electrostatic chuck that holds the edge ring ER. However, a bipolar electrostatic chuck may be used instead of the monopolar electrostatic chuck, and a monopolar electrostatic chuck may be used instead of the bipolar electrostatic chuck.

On the outside of the edge ring ER, a cover ring CR is disposed to surround the edge ring ER. The cover ring CR has an annular shape. The cover ring CR covers an upper surface of the insulator 27. The cover ring CR is formed of, for example, an insulating material such as quartz. The cover ring CR may be formed of a conductive material such as silicon or silicon carbide. An outer peripheral portion of the edge ring ER is disposed to overlap with an inner peripheral portion of the cover ring CR when viewed from above. Further, an outer peripheral portion of the cover ring CR is disposed on the outside of the outer peripheral portion of the edge ring ER and surrounds the outer peripheral portion of the edge ring ER.

The plasma processing apparatus 1 further includes a lifter 70. The lifter 70 includes a lifter 71 and a lifter 72. The lifter 71 includes a plurality of lift pins 711 and an actuator 712. Each of the plurality of lift pins 711 is inserted into a corresponding one of a plurality of through-holes 161 formed in the base plate 18 and the electrostatic chuck 20. The actuator 712 raises and lowers the plurality of lift pins 711. By the raising and lowering by the actuator 712, the plurality of lift pins 711 can protrude upward from the substrate support surface 20a and retract downward relative to the substrate support surface 20a. As the actuator 712, for example, a motor such as a DC motor, a stepping motor, or a linear motor, an air-driven mechanism such as an air cylinder, or a piezo actuator can be used. The lifter 71 raises and lowers the plurality of lift pins 711 when transferring the substrate W between the transfer robot TR and the substrate support 16.

The lifter 72 includes a plurality of lift pins 721 and an actuator 722. Each of the plurality of lift pins 721 is inserted into a corresponding one of a plurality of through-holes 162 formed in the insulator 27 and a corresponding one of a plurality of through-holes CRh formed in the cover ring CR. The actuator 722 raises and lowers the plurality of lift pins 721. As the actuator 722, for example, the same type as the actuator 712 can be used.

Each of the plurality of lift pins 721 includes a lower portion 723 and an upper portion 724. Each of the lower portion 723 and the upper portion 724 has a rod shape. A diameter of the lower portion 723 is larger than a diameter of the upper portion 724. The upper portion 724 extends upward from the lower portion 723.

A diameter of each of the plurality of through-holes 162 is slightly larger than a diameter of the lower portion 723 of each of the plurality of lift pins 721. A diameter of each of the plurality of through-holes CRh is slightly larger than a diameter of the upper portion 724 of each of the plurality of lift pins 721 and smaller than the diameter of the lower portion 723 of each of the plurality of lift pins 721.

Each of the plurality of lift pins 721 can be positioned at each of a standby position, a first support position, and a second support position. The standby position is a position where an upper end surface 724t of the upper portion 724 is below a lower surface of the edge ring ER. In a state where the plurality of lift pins 721 are at the standby position, the edge ring ER and the cover ring CR are supported by the electrostatic chuck 20 and the insulator 27, respectively, without being lifted by the plurality of lift pins 721.

The first support position is a position above the standby position. In a state where each of the plurality of lift pins 721 is disposed at the first support position, the upper end surface 724t of the upper portion 724 is positioned above an upper surface of the cover ring CR, and an upper end surface 723t of the lower portion 723 is positioned below a lower surface of the cover ring CR. In a state where the plurality of lift pins 721 are disposed at the first support position, the upper end surface 724t of the upper portion 724 abuts against a surface defining a recess ERr formed in a lower surface of the edge ring ER. As a result, the plurality of lift pins 721 support the edge ring ER.

The second support position is a position above the first support position. In a state where each of the plurality of lift pins 721 is disposed at the second support position, the upper end surface 723t of the lower portion 723 is positioned above an upper surface of the insulator 27. In a state where the plurality of lift pins 721 are disposed at the second support position, the upper end surface 723t of the lower portion 723 abuts against a lower surface of the cover ring CR. As a result, the plurality of lift pins 721 support the cover ring CR. Note that in a case where the edge ring ER is positioned on an inner peripheral portion of the cover ring CR, the upper end surface 724t of the upper portion 724 abuts against the surface defining the recess ERr, and the plurality of lift pins 721 support both the cover ring CR and the edge ring ER.

When transferring only the edge ring ER between the transfer robot TR and the substrate support 16, the lifter 72 moves the plurality of lift pins 721 to the first support position. When transferring both the edge ring ER and the cover ring CR or only the cover ring CR between the transfer robot TR and the substrate support 16, the lifter 72 moves the plurality of lift pins 721 to the second support position.

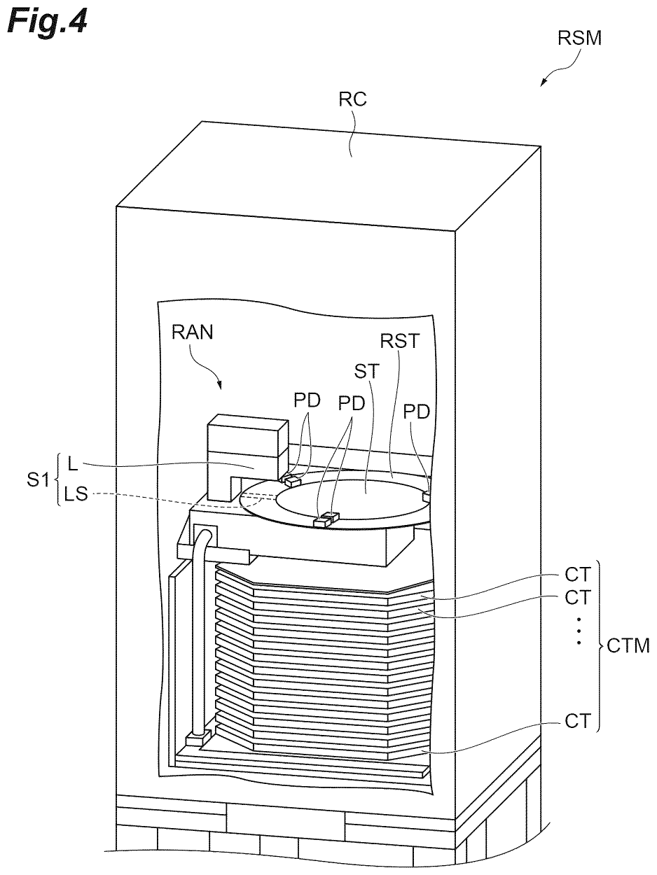

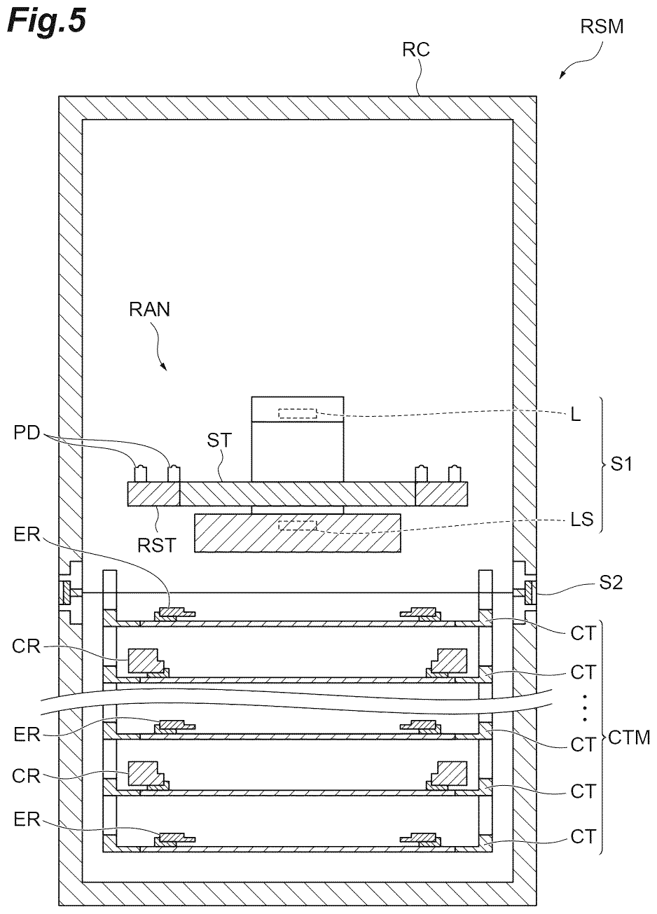

Hereinafter, details of the aligner RAN and the stocker module RSM will be described with reference to FIGS. 4 and 5. FIG. 4 is a perspective view showing the stocker module according to one embodiment. FIG. 4 is a partially cutaway perspective view illustrating the inside of the stocker module RSM. FIG. 5 is an end view of the stocker module according to one embodiment.

The stocker module RSM includes a chamber RC. The chamber RC is configured such that its interior space can be depressurized. FIG. 4 illustrates the chamber RC in a state where a part thereof is cut away to illustrate the interior space. In the chamber RC, the aligner RAN and a cassette module CTM are disposed. The aligner RAN is disposed above the cassette module CTM. The cassette module CTM includes a plurality of cassettes CT. Each of the plurality of cassettes CT is configured to accommodate a ring member R therein.

A plurality of ring members R are accommodated in the cassette module CTM. The plurality of ring members R may include edge rings ER and cover rings CR. As shown in FIG. 5, in the cassette module CTM, edge rings ER and cover rings CR are alternately arranged. The aligner RAN and the cassette module CTM may be configured to be movable in the vertical direction. For example, a ring member R is carried out from a cassette CT disposed at a transfer position in the chamber RC. The cassette module CTM may move in the vertical direction to position the ring member R to be carried out at the transfer position in the chamber RC. In the cassette module CTM, the ring members R may be carried out in order starting from the ring member R disposed at the bottom among the plurality of ring members R.

The aligner RAN has a stage ST and an optical sensor S1. The stage ST is configured to support a ring member R placed thereon. The optical sensor S1 is configured to detect a shape of the ring member R placed on the stage ST.

In one embodiment, the stage ST is configured to rotate together with the ring member R placed thereon. For example, the stage ST may include a support RST configured to rotate and configured to support the ring member R. The support RST is formed of a material through which visible light can pass. In one example, the support RST is formed of glass. The support RST may include a plurality of pads PD. The plurality of pads may include pads for the edge ring ER and pads for the cover ring CR. The pads for the edge ring ER are disposed inside the pads for the cover ring CR. The aligner RAN may move in the vertical direction so that the support RST of the stage ST is disposed at the transfer position in the chamber RC.

In one embodiment, the optical sensor S1 includes a line sensor LS and a light source L. The line sensor LS is configured to detect an outer edge and an inner edge of the ring member R. The light source L emits light toward the line sensor LS. In one example, the light source L may emit laser light. For example, the line sensor LS and the light source L are disposed facing each other in the vertical direction such that the stage ST is positioned therebetween. The line sensor LS may be disposed below the support RST to intersect with the inner edge of the ring member R and the outer edge of the ring member R as seen from the light source L. In one example, while the stage ST and the ring member R placed on the stage rotate together, the light source L emits light toward the line sensor LS. The line sensor LS detects light onto which the inner edge of the ring member R and the outer edge of the ring member R are projected. The optical sensor S1 detects the shape of the ring member R from the light detected by the line sensor LS.

The aligner RAN may be configured to perform adjustment (alignment) of a position of the ring member R disposed on the stage ST. The optical sensor S1 may be configured to optically detect a position of the ring member on the support RST. The aligner RAN may be configured to perform adjustment of the position of the ring member R in accordance with the position detected by the optical sensor S1. In one embodiment, the aligner RAN is configured to enable detection of the edge ring ER and the cover ring CR and alignment of each of them. In one example, the aligner RAN may be configured to be capable of performing alignment of the edge ring ER at an inner portion of the line sensor LS and performing alignment of the cover ring CR at an outer portion of the line sensor.

In one embodiment, the stocker module RSM may further include an optical sensor S2. The optical sensor S2 is configured to detect a thickness of the ring member R. In one example, the optical sensor S2 is a mapping sensor. The optical sensor S2 may include a light source that emits laser light in a horizontal direction and a light sensor that receives the laser light emitted from the light source. The cassette CT may include a side surface in which a cutout is formed. The cutout is positioned so that the laser light is irradiated onto the ring member R accommodated in the cassette CT.

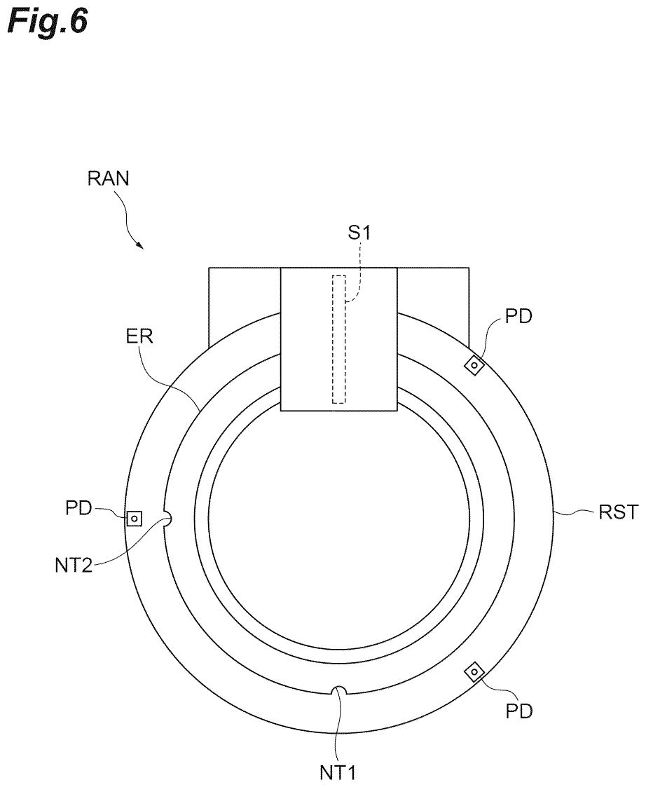

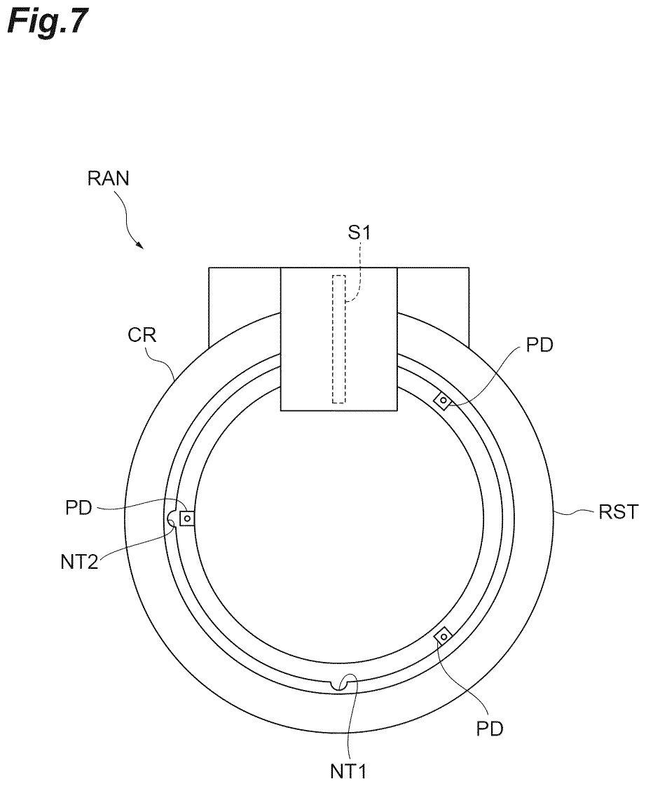

Hereinafter, the shape of the ring member R and feature information of the ring member R extracted from the shape of the ring member R will be described with reference to FIGS. 6 and 7. FIG. 6 is a plan view of an edge ring and an aligner according to one embodiment. FIG. 6 shows the edge ring ER placed on the support RST of the aligner RAN. FIG. 7 is a plan view of a cover ring and an aligner according to one embodiment. FIG. 7 shows the cover ring CR placed on the support RST of the aligner RAN.

The identification processor IU acquires feature information indicating a feature of the ring member R from the shape of the ring member R acquired by the optical sensor S1. In one embodiment, the feature of the ring member R may include at least one of an inner diameter of the ring member R, an outer diameter of the ring member R, or a thickness of the ring member R. The phrase “may include at least one” means that the ring member R may include one of the inner diameter, the outer diameter, or the thickness as its feature, or may include a plurality thereof. The inner diameter and the outer diameter of the ring member may be determined from the curvatures of the inner edge and the outer edge of the ring member.

In the examples of FIGS. 6 and 7, a first notch NT1 and a second notch NT2 are formed in the ring member R. The feature of the ring member includes the first notch NT1 and the second notch NT2 as the at least one notch. As shown in FIG. 6, in the edge ring ER, the first notch NT1 and the second notch NT2 are formed on the outer edge thereof. As shown in FIG. 7, in the cover ring CR, the first notch NT1 and the second notch NT2 are formed on the inner edge thereof. In one embodiment, the identification processor IU may acquire the thickness of the ring member R detected by the optical sensor S2 as feature information indicating the feature of the ring member R.

In one embodiment, the feature of the ring member R may include the number of notches formed in the ring member R. In the examples of FIGS. 6 and 7, the number of the at least one notch is two. In a case where no notch is formed in the ring member R, the number of notches is set to 0. In one embodiment, the feature of the ring member R may include a relative positional relationship between the first notch NT1 and the second notch NT2. The relative positional relationship between the first notch NT1 and the second notch NT2 is, for example, an angle between the first notch NT1 and the second notch NT2 with respect to the center of the ring member R. The relative positional relationship between the first notch NT1 and the second notch NT2 may be a distance between the first notch NT1 and the second notch NT2.

Each of the plurality of ring members R is a ring member R for a corresponding process module among the plurality of process modules PM1 to PM6. In the substrate processing system PS, each of the plurality of ring members R is transferred to the corresponding process module. The memory MU is configured to store a table including feature information indicating a feature of each of the plurality of ring members R, the feature information being associated with an identifier of each of the plurality of process modules PM1 to PM6. For example, in the table, feature information indicating a feature of a specific ring member R and an identifier of a specific process module corresponding to the specific ring member R are stored in association with each other.

The identification processor IU refers to the table stored in the memory MU and identifies one of the plurality of process modules PM1 to PM6 to which the ring member R is to be transferred, from the identifier associated with the feature information indicating the feature of the ring member R. The process module to which the ring member R is to be transferred is a process module corresponding to the ring member R among the plurality of process modules PM1 to PM6.

The feature information indicating the feature of the ring member R is stored in the table stored in the memory MU in association with the identifier of the process module corresponding to the ring member R. According to the substrate processing system PS, by referring to the table stored in the memory MU, one of the plurality of process modules PM1 to PM6 corresponding to the ring member R is identified from the feature information indicating the feature of the ring member R extracted from the shape of the ring member R.

The controller MC controls the transfer robot TR. The controller MC may control the transfer robot TR to transfer the ring member R on a path between the cassette module CTM and the aligner RAN in the stocker module RSM. The controller MC may control the transfer robot TR to transfer the ring member R to a designated process module among the plurality of process modules PM1 to PM6.

In one embodiment, the controller MC transfers the ring member R onto the stage ST of the aligner RAN before transferring the ring member R to a designated process module among the plurality of process modules PM1 to PM6. The controller MC acquires an identifier of a process module among the plurality of process modules PM1 to PM6 to which the ring member R transferred onto the stage ST is to be transferred, the process module being identified by the identification processor IU by referring to the table stored in the memory MU based on the feature information of the ring member R transferred onto the stage ST. The controller MC determines whether the identifier of the designated process module matches the identifier of the process module to which the ring member is to be transferred.

In one embodiment, the controller MC transfers the ring member R onto the stage ST of the aligner RAN after carrying out the ring member R from a process module. The controller MC acquires an identifier of a process module among the plurality of process modules PM1 to PM6 to which the ring member R transferred onto the stage ST is to be transferred, the process module being identified by the identification processor IU by referring to the table stored in the memory MU based on the feature information of the ring member R transferred onto the stage ST. The controller MC determines whether the identifier of the process module from which the ring member R was carried out matches the identifier of the process module to which the ring member R is to be transferred.

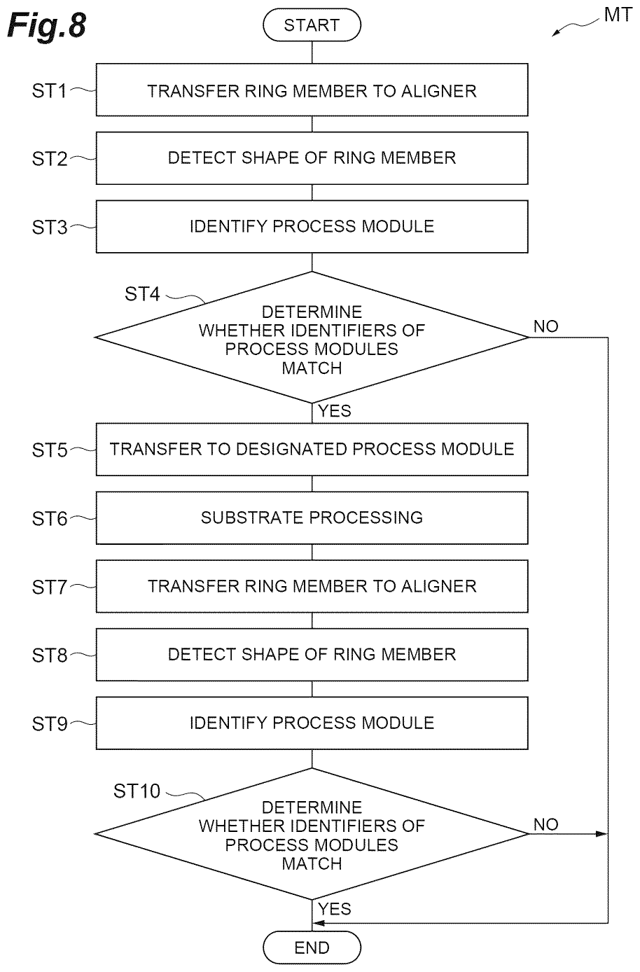

FIG. 8 is a flowchart showing a substrate processing method according to one exemplary embodiment. Hereinafter, an example of executing a substrate processing method (hereinafter referred to as “method MT”) will be described with reference to FIG. 8. The method MT is performed using the substrate processing system PS. Hereinafter, control of each configuration and each part of the substrate processing system PS in the method MT will also be described. Note that the method MT may be performed using a substrate processing system other than the substrate processing system PS.

The method MT starts at step ST1. In step ST1, the ring member R is transferred to the aligner RAN. In one example, the ring member R is transferred by the transfer robot TR from the cassette CT disposed at the bottom of the cassette module CTM onto the stage ST of the aligner RAN. In one embodiment, step ST1 may be performed before transferring the ring member R to a designated process module among the plurality of process modules PM1 to PM6. In the example of FIG. 8, step ST1 is performed before step ST5 of transferring to the designated process module.

After step ST1, step ST2 is performed. In step ST2, the shape of the ring member R transferred to the aligner RAN is detected. For example, the shape of each of the inner edge and the outer edge of the ring member R is detected by the optical sensor S1. In one embodiment, the shape of the ring member R may be the thickness of the ring member R. The thickness of the ring member R may be detected by the optical sensor S2 disposed in the stocker module RSM before step ST2.

After step ST2, step ST3 is performed. In step ST3, feature information indicating a feature of the ring member R is extracted from the shape of the ring member R. After the feature information is extracted, the table stored in the memory MU is referred to, and one of the plurality of process modules PM1 to PM6 to which the ring member R is to be transferred is identified from the identifier associated with the feature information in the table stored in the memory MU.

For example, in the table stored in the memory MU, the identifier of the process module PM1 and the feature information of the ring member R corresponding to the process module PM1 are stored in association with each other. In the table stored in the memory MU, the identifier of the process module PM1 and an identifier of the ring member R corresponding to the process module PM1 may be stored in association with each other, and the identifier of the ring member R and the feature information of the ring member R may be stored in association with each other.

In one embodiment, the method MT may include step ST4. Step ST4 is performed after step ST3. In step ST4, it is determined whether the identifier of the designated process module matches the identifier of the process module to which the ring member R is to be transferred identified in step ST3. In a case where it is not determined that they match in step ST4 (in a case where the result of the determination in step ST4 of FIG. 8 is “NO”), the method MT may end. In this case, for example, the method MT ends abnormally. Before the method MT ends abnormally, the substrate processing system PS may notify an operator that the identifier of the designated process module and the identifier of the process module to which the ring member R is to be transferred do not match. In a case where it is determined that they match in step ST4 (in a case where the result of the determination in step ST4 of FIG. 8 is “YES”), step ST5 may be performed.

In one example, the method MT may include step ST5 and step ST6. In step ST5, the ring member R is transferred to a designated process module among the plurality of process modules PM1 to PM6. For example, the cover ring CR is transferred through the lifter 70 onto the insulator 27 of the substrate support 16 in the processing chamber 10 of the designated process module. For example, the edge ring ER is transferred through the lifter 70 onto the ring support surface 20b of the substrate support 16 in the processing chamber 10 of the designated process module.

After step ST5, the substrate W may be transferred to the designated process module (not shown). For example, the substrate W is transferred onto the substrate support surface 20a to be surrounded by the edge ring ER transferred in step ST5.

Step ST6 is performed after step ST5. In step ST6, substrate processing is performed on the substrate W on the substrate support 16. The substrate processing may be plasma processing. The substrate processing may include etching processing and film deposition processing.

After step ST6, the substrate W may be carried out from the designated process module (not shown). For example, the substrate W is transferred to the transfer chamber ACH through the transfer chamber VCH.

In one embodiment, the method MT may include step ST7, step ST8, step ST9, and step ST10. Step ST7 is performed after step ST6. In step ST7, after the ring member R is carried out from the designated process module, the ring member R is transferred to the aligner RAN. In one example, the ring member R is transferred by the transfer robot TR from on the substrate support 16 in the processing chamber 10 of the designated process module onto the stage ST of the aligner RAN.

Step ST8 is performed after step ST7. In step ST8, similarly to step ST2, the shape of the ring member R transferred to the aligner RAN is detected. Step ST9 is performed after step ST8. In step ST9, similarly to step ST3, feature information indicating a feature of the ring member R is extracted from the shape of the ring member R, and the process module to which the ring member R is to be transferred is identified.

Step ST10 is performed after step ST9. In step ST10, it is determined whether the identifier of the process module from which the ring member R was carried out matches the identifier of the process module to which the ring member R is to be transferred, as identified in step ST9. In a case where it is not determined that they match in step ST10 (in a case where the result of the determination in step ST10 of FIG. 8 is “NO”), the method MT may end. In this case, in one example, the method MT ends abnormally. Before the method MT ends abnormally, the substrate processing system PS may notify an operator that the identifier of the designated process module and the identifier of the process module from which the ring member R was carried out do not match. In a case where it is determined that they match in step ST10 (in a case where the result of the determination in step ST10 of FIG. 8 is “YES”), the method MT may end. In this case, in one example, the method MT ends normally.

Although various exemplary embodiments have been described above, various additions, omissions, substitutions, and modifications may be made without being limited to the exemplary embodiments described above. In addition, other embodiments can be formed by combining elements in different embodiments.

The substrate processing system PS is not necessarily limited to that shown in FIG. 1. For example, the number of process modules and/or the number of transfer modules in the substrate processing system may be different from those shown in FIG. 1. For example, the number of load ports may be five or more, and the number of load ports may be any number. Further, the substrate processing system may be a system (a so-called loader-type system) in which a plurality of module groups each including a process module and a load lock module are connected to a loader module. Further, the substrate processing system may be a system (a so-called cluster-type system) in which two or more process modules are arranged around a transfer module to surround the transfer module and connected thereto.

In one embodiment, the aligner RAN may be connected to the transfer chamber ACH of the loader module LM. In this case, the stocker module RSM may be connected to the transfer chamber ACH.

The method MT need not include steps ST5 to ST10. The method MT need not include steps ST1 to ST6. In a case where the method MT does not include steps ST1 to ST6, the method MT starts at step ST7.

Here, various exemplary embodiments included in the present disclosure are described in the following [E1] to [E15].

### E1

A substrate processing system including:
a vacuum transfer module having a transfer chamber configured to be depressurized and a transfer robot configured to transfer a substrate through the transfer chamber;
a controller configured to control the transfer robot;
a plurality of process modules each having a processing chamber connected to the transfer chamber and a substrate support in the processing chamber, and each being configured to perform substrate processing on a substrate on the substrate support;
an aligner having a stage configured to support a ring member placed thereon and an optical sensor configured to detect a shape of the ring member placed on the stage;
a memory configured to store a table including feature information indicating a feature of each of a plurality of ring members, the feature information being associated with an identifier of each of the plurality of process modules; and
an identification processor configured to extract the feature information of the ring member from the shape of the ring member detected by the optical sensor, and refer to the table stored in the memory to identify one of the plurality of process modules to which the ring member is to be transferred, from the identifier associated with the feature information.

### E2

The substrate processing system according to E1, wherein the feature includes at least one of an inner diameter of the ring member, an outer diameter of the ring member, or a thickness of the ring member.

### E3

The substrate processing system according to E1 or E2, wherein the feature includes the number of notches formed in the ring member.

### E4

The substrate processing system according to any one of E1 to E3, wherein
the ring member includes a first notch and a second notch, and
the feature includes a relative positional relationship between the first notch and the second notch.

### E5

The substrate processing system according to any one of E1 to E4, wherein
the ring member is an edge ring configured to surround a substrate on the substrate support or a cover ring configured to surround the edge ring.

### E6

The substrate processing system according to any one of E1 to E5, wherein
the stage is configured to rotate together with the ring member placed thereon, and
the optical sensor includes:
   a line sensor configured to detect an outer edge and an inner edge of the ring member; and
   a light source configured to emit light toward the line sensor.

### E7

The substrate processing system according to any one of E1 to E6, further including:
a load lock module connected to the transfer chamber of the vacuum transfer module; and
an atmospheric transfer module having another transfer chamber connected to the load lock module and another transfer robot configured to transfer the substrate through the other transfer chamber,
wherein the aligner is connected to the other transfer chamber of the atmospheric transfer module.

### E8

The substrate processing system according to any one of E1 to E6, wherein
the aligner is connected to the transfer chamber of the vacuum transfer module.

### E9

The substrate processing system according to E8, further including:
a stocker module that is connected to the transfer chamber of the vacuum transfer module and is configured to accommodate the ring member therein,
wherein the aligner is in the stocker module.

### E10

The substrate processing system according to E9, wherein
the feature includes a thickness of the ring member, and
the stocker module includes another optical sensor configured to detect the thickness.

### E11

### The Substrate Processing System According to Any One of E1 to E10, wherein

the controller is configured to:
   control the transfer robot to transfer the ring member onto the stage of the aligner before transferring the ring member to a designated process module among the plurality of process modules;
   acquire an identifier of one of the plurality of process modules to which the ring member transferred onto the stage is to be transferred, the process module being identified by the identification processor by referring to the table stored in the memory based on the feature information of the ring member transferred onto the stage; and
   determine whether the identifier of the designated process module matches the identifier of the process module to which the ring member is to be transferred.

### E12

The substrate processing system according to any one of E1 to E11,
wherein the controller is configured to:
   control the transfer robot to transfer the ring member onto the stage of the aligner after carrying out the ring member from a process module;
   acquire an identifier of one of the plurality of process modules to which the ring member transferred onto the stage is to be transferred, the process module being identified by the identification processor by referring to the table stored in the memory based on the feature information of the ring member transferred onto the stage; and
   determine whether the identifier of the process module from which the ring member was carried out matches the identifier of the process module to which the ring member is to be transferred.

### E13

A substrate processing method performed in a substrate processing system,
the substrate processing system including:
   a plurality of process modules each configured to perform substrate processing;
   an aligner configured to detect a feature of a ring member; and
   a memory configured to store a table including feature information indicating a feature of each of a plurality of ring members, the feature information being associated with an identifier of each of the plurality of process modules, and
the substrate processing method including:
   transferring a ring member to the aligner;
   after the transferring, detecting a shape of the ring member transferred to the aligner; and
   after the detecting, extracting the feature information of the ring member from the detected shape of the ring member, and referring to the table stored in the memory to identify one of the plurality of process modules to which the ring member is to be transferred, from the identifier associated with the feature information.

### E14

The substrate processing method according to E13, wherein
the transferring is performed before transferring the ring member to a designated process module, and
the method further includes:
after the extracting, determining whether the identifier of the designated process module matches the identifier of the process module to which the ring member is to be transferred.

### E15

The substrate processing method according to E13 or E14,
wherein the transferring is performed after carrying out the ring member from a process module, and
the method further includes:
after the extracting, determining whether the identifier of the process module from which the ring member was carried out matches the identifier of the process module to which the ring member is to be transferred.

The processing methods described in E13 to E15 may be performed in the substrate processing system described in E1 to E12.

From the foregoing description, it will be understood that various embodiments of the present disclosure have been described herein for purposes of illustration, and that various modifications may be made without departing from the scope and gist of the present disclosure. Accordingly, the various embodiments disclosed herein are not intended to be limiting, with the true scope and gist being indicated by the appended claims.

It is to be understood that not all aspects, advantages and features described herein may necessarily be achieved by, or included in, any one particular example. Indeed, having described and illustrated various examples herein, it should be apparent that other examples may be modified in arrangement and detail.

What is claimed is:

1. A substrate processing system comprising:
a vacuum transfer module having a transfer chamber configured to be depressurized and a transfer robot configured to transfer a substrate through the transfer chamber;
a controller configured to control the transfer robot;
a plurality of process modules each having a processing chamber connected to the transfer chamber and a substrate support in the processing chamber, and each being configured to perform substrate processing on a substrate on the substrate support;
an aligner having a stage configured to support a ring member placed thereon and an optical sensor configured to detect a shape of the ring member placed on the stage;
a memory configured to store a table including feature information indicating a feature of each of a plurality of ring members, the feature information being associated with an identifier of each of the plurality of process modules; and
an identification processor configured to extract the feature information of the ring member from the shape of the ring member detected by the optical sensor, and refer to the table stored in the memory to identify one of the plurality of process modules to which the ring member is to be transferred, from the identifier associated with the feature information.

2. The substrate processing system according to claim 1, wherein
the feature includes at least one of an inner diameter of the ring member, an outer diameter of the ring member, or a thickness of the ring member.

3. The substrate processing system according to claim 1, wherein
the feature includes the number of notches formed in the ring member.

4. The substrate processing system according to claim 1, wherein
the ring member includes a first notch and a second notch, and
the feature includes a relative positional relationship between the first notch and the second notch.

5. The substrate processing system according to claim 1, wherein
the ring member is an edge ring configured to surround a substrate on the substrate support or a cover ring configured to surround the edge ring.

6. The substrate processing system according to claim 1, wherein
the stage is configured to rotate together with the ring member placed thereon, and
the optical sensor includes:
a line sensor configured to detect an outer edge and an inner edge of the ring member; and
a light source configured to emit light toward the line sensor.

7. The substrate processing system according to claim 1, further comprising:
a load lock module connected to the transfer chamber of the vacuum transfer module; and
an atmospheric transfer module having another transfer chamber connected to the load lock module and another transfer robot configured to transfer the substrate through the other transfer chamber,
wherein the aligner is connected to the other transfer chamber of the atmospheric transfer module.

8. The substrate processing system according to claim 1, wherein
the aligner is connected to the transfer chamber of the vacuum transfer module.

9. The substrate processing system according to claim 8, further comprising:
a stocker module that is connected to the transfer chamber of the vacuum transfer module and is configured to accommodate the ring member therein,
wherein the aligner is in the stocker module.

10. The substrate processing system according to claim 9, wherein
the feature includes a thickness of the ring member, and
the stocker module includes another optical sensor configured to detect the thickness.

11. The substrate processing system according to claim 1, wherein
the controller is configured to:
control the transfer robot to transfer the ring member onto the stage of the aligner before transferring the ring member to a designated process module among the plurality of process modules;
acquire an identifier of one of the plurality of process modules to which the ring member transferred onto the stage is to be transferred, the process module being identified by the identification processor by referring to the table stored in the memory based on the feature information of the ring member transferred onto the stage; and
determine whether the identifier of the designated process module matches the identifier of the process module to which the ring member is to be transferred.

12. The substrate processing system according to claim 1,
wherein the controller is configured to:
control the transfer robot to transfer the ring member onto the stage of the aligner after carrying out the ring member from a process module;
acquire an identifier of one of the plurality of process modules to which the ring member transferred onto the stage is to be transferred, the process module being identified by the identification processor by referring to the table stored in the memory based on the feature information of the ring member transferred onto the stage; and
determine whether the identifier of the process module from which the ring member was carried out matches the identifier of the process module to which the ring member is to be transferred.

13. A substrate processing method performed in a substrate processing system,
the substrate processing system comprising:
a plurality of process modules each configured to perform substrate processing;
an aligner configured to detect a feature of a ring member; and
a memory configured to store a table including feature information indicating a feature of each of a plurality of ring members, the feature information being associated with an identifier of each of the plurality of process modules, and
the substrate processing method comprising:
transferring a ring member to the aligner;
after the transferring, detecting a shape of the ring member transferred to the aligner; and
after the detecting, extracting the feature information of the ring member from the detected shape of the ring member, and referring to the table stored in the memory to identify one of the plurality of process modules to which the ring member is to be transferred, from the identifier associated with the feature information.

14. The substrate processing method according to claim 13, wherein
the transferring is performed before transferring the ring member to a designated process module, and
the method further comprises:
after the extracting, determining whether the identifier of the designated process module matches the identifier of the process module to which the ring member is to be transferred.

15. The substrate processing method according to claim 13,
wherein the transferring is performed after carrying out the ring member from a process module, and
the method further comprises:
after the extracting, determining whether the identifier of the process module from which the ring member was carried out matches the identifier of the process module to which the ring member is to be transferred.
